(19) United States
(12) Patent Application Publication
(10) Pub. No.: US 2003/0085198 A1
(43) Pub. Date: May 8, 2003

(54) Method of detecting etching process end point in semiconductor fabricating equipment and detector therefor

(76) Inventors: Hun Jung Yi, Kyunggi-do (KR); Pil Kwon Jun, Seoul (KR); Ki Seok Lee, Taejon-city (KR); Woo Il Kim, Seoul (KR)

Correspondence Address: VOLENTINE FRANCOS, P.L.L.C., Suite 150, 12200 Sunrise Valley Drive, Reston, VA, 20191, US

(21) Appl. No.: 10/121,709

(22) Filed: Apr. 15, 2002

(30) Foreign Application Priority Data
Nov. 8, 2001 (KR) 2001-69422

(51) Int. Cl. C23F 1/00; H01L 21/00

(52) U.S. Cl. 216/60; 156/345.25; 438/14

(57) ABSTRACT

An etching end point detector and its related method of use detect a point of time when an etching process ends by using plasma light generated during a plasma process in a chamber of plasma etching equipment. The detector comprises an optical device receiving light generated in a chamber during the etching process and producing from the light a plurality of optical signals having different corresponding wavelengths; signal converting means receiving the plurality of optical signals and converting the plurality of optical signals into corresponding light intensity values indicating an intensity of the corresponding optical signal; and a signal processor accumulating selected ones of the light intensity values corresponding to predetermined wavelengths to produce an EPD value, and in response to the EPD value, determining an end point of the etching process.

### CROSS REFERENCE TO RELATED APPLICATIONS

This application claims the benefit of Korea Patent Application No. 2001-69422, filed on Nov. 8, 2001, under 35 U.S.C. § 119, the entirety of which is hereby incorporated by reference for all purposes as if fully set forth herein.

### BACKGROUND

1. Field of the Invention

The present invention relates to semiconductor fabricating equipment that can produce semiconductor devices on a large scale and more particularly to a method and apparatus for detecting an etching process end point in semiconductor device fabricating equipment to terminate a plasma process on wafers.

2. Brief Description of Related Art

Recently, an etching method using plasma has been widely used for processes to fabricate semiconductor devices and LCD substrates. According to a typically-used etching method, an object like a semiconductor wafer is positioned for treatment at a lower electrode in parallel to an upper electrode. A high frequency voltage is applied between the electrodes to generate plasma. Then, the object is etched adequately to a preset pattern. According to such an etching method, to perform a precise etching process, it is necessary to accurately detect a point of time when the etching process ends. For instance, a method using an emitted light spectroscope analysis has been widely utilized. According to such an end point detecting method, an actuated species is selected for easy observation, like a substance decomposed from an etching gas or a reaction product like ions, and an etching end point of time is detected on the basis of changes in the emitted light intensity relevant to a preset wavelength. For instance, when a silicon oxide layer is etched with CF-group gas like CF₄, a light of a preset wavelength (i.e., 483.5 nm) that is emitted from a CO containing material as a reaction forming product is detected, and a point of time when the etching process ends is determined on the basis of a point of time when a particular light intensity is detected. Selectively, when a silicone nitride layer is etched by using a CF-group gas like CF₄, a light of a preset wavelength (i.e., 674 nm) emitted from an N containing material as a reaction forming product is detected and then utilized to detect an etching end point. Therefore, in the conventional end point detecting method, light of different wavelengths is utilized for different etching processes.

According to the conventional end point detecting method using an emitted light spectroscope analysis, a point of time is determined when an etching process is terminated on an object and its lower layer is exposed. Accordingly, there is a change in the intensity of light having a preset wavelength. However, it is difficult to make a real time detection and to avoid over-etching. As a result, a lower layer is also etched and damaged. In other words, the problem of over-etch onto the lower layer can result in a serious negative effect on production of a final semiconductor device, that is, a defective product. For instance, when a polycrystalline silicone layer is treated for forming a gate electrode as a lower layer on a gate oxide layer, the gate oxide layer is more greatly damaged because it has a smaller thickness than the polycrystalline silicon layer.

Moreover, the end point detector using an emitted light spectroscope has a motor-driven diffraction grating. When the light generated from the plasma chamber is received by the diffraction grating through an optical fiber, the diffraction grating acts to divide the received light according to its wavelengths. Only a wavelength closely related to an end point detecting process is selected out of all those divided light wavelengths to measure the light intensity. Thus, in order to measure the intensity of light of another wavelength, the diffraction grating should be driven by a motor to make a change in its light receiving angle. Therefore, quite a long period of time is spent in getting the diffraction grating driven to perform light spectroscope analysis on a wide range of light from 200-800 nm. Thus, in order to be utilized for a process, a wavelength of light that makes a great change in its intensity in the course of the process should be selected to measure the light intensity according to the elapsed time.

Also, it is well-known that such a method using a single wavelength has a difficulty in accurately detecting a point of time that the etching process ends if the whole area of a layer to be etched is small. In other words, if a minor-contact is etched, most of a wafer is covered with photo resist and only a very small part is a silicon oxide layer. Even if an etching chemical species has a greater reactivity to the silicon oxide layer than the photo resist, part of it will react with the photo resist to generate a byproduct. Light generated in the reaction is observed as a noise signal. If the area of the silicon oxide portion is reduced to less than 0.5% of the total area of the wafer, it is known to be difficult to detect noise because it is buried in most observable signals. Also, besides a change in the quality of a layer, there may be another change in the light intensity due to a plurality of factors like a change in density of plasma itself, turbidity of an EPD measuring window, or the like.

There has been disclosed a method to detect an end point by using a ratio of two selected wavelengths, one that is closely related to the process and another that represents properties of plasma itself, to overcome a problem of a reduction in detection sensitivity. However, there is a problem in such a method in that it is impossible to make a real time analysis because the end point should be measured with a change of wavelengths in the same way as in the conventional single diffraction grating method, by operating a motor to change the diffraction grating angle.

In order to make a real time analysis, the prior art equipment requires two diffraction gratings and detectors in the prior art. However, even when two wavelengths are utilized, there still may be a problem of a reduction in detection sensitivity because of an identical cause when a minor-contact is etched. Therefore, it is preferable that measurements should be taken for all wavelengths of the related areas. If the etching end point is sequentially detected by a method in which an adjustment needs to be made to angles of the diffraction gratings, it takes a long time to measure the whole spectrum, thereby deteriorating its practicality. Development of a new spectrum measuring method is needed.

In a very new spectrum measuring method, all of the wavelengths of the spectrum are simultaneously measured by using a charge-coupled device (CCD) as a photoelectric transducer without driving a diffraction grating. According to such a method, it is a critical point to select a wavelength that can best detect and indicate a point of time when the etching process ends after all the spectra are read in a computer for a statistical analysis. However, the statistical processing method has a disadvantage that a statistical operation may be a big burden requiring a long period of time, so that it is difficult to apply the method to an actual semiconductor device fabricating line.

As described above, a superior technique with a higher sensitivity is required to make a precise detection or a point of time that ends the etching process when a minor-contact etching process is performed in a plasma chamber. In addition, it is urgent to develop a real time detection technique with a superior detection sensitivity that can prevent an over-etch by making a reduction in the burden of arithmetic operations required to precisely detect an etching end point.

### SUMMARY OF THE INVENTION

It is an object of the present invention to solve the aforementioned problem and provide an etching end point detector and a related method for detecting a point of real time to terminate an etching process of a layer where a plasma process is performed, without making an over-etch or damage to a lower layer.

It is another object of the present invention to provide an end point detector and a related method that can improve the sensitivity to detect a point of time that an etching process ends by using a plurality of light wavelengths.

It is still another object of the invention to provide an end point detector and a related method that can increase a speed to operate a plurality of wavelengths in a hardware system.

In order to accomplish the aforementioned objects in accordance with an aspect of the present invention, there is provided an end point detector to detect a point of time when an etching process ends by using plasma light generated during a plasma process in a chamber of plasma etching equipment, the detector comprising: an optical device for diffracting plasma light generated in the chamber according to the light's spectrum and turning the light into a plurality of optical signals having different wavelengths; a photoelectric transducer including a plurality of unit converting elements having their own unique addresses for receiving the plurality of optical signals and converting the optical signals into corresponding electric signals having levels corresponding to intensities of the corresponding optical signals; an A/D converter for converting the plurality of electric signals of the photoelectric transducer and simultaneously outputting the transformed light intensity data and the unique addresses of the unit converting elements as digital data; and a signal processing device for differentiating the light intensity data and unique addresses, performing a light intensity data synthesizing process of accumulatively storing the light intensity data in sequence to the unique addresses by comparing and determining whether each unique address is identical to a value corresponding to a preset wavelength, until the unique address is the last address, and providing the accumulatively stored light intensity data in real time to a control system that operates to terminate the etching process of the plasma etching equipment.

Also, in accordance with another aspect of the present invention, there is provided a method of detecting an end point using plasma light generated in the chamber of plasma etching equipment during a plasma process, the method comprising the steps of: setting up a diffraction grating which diffracts the plasma light generated in the chamber according to the light emitting spectrum and turning the light into a plurality of optical signals having different wavelengths, a photoelectric transducer, including a plurality of unit converting elements having their own unique addresses, which receives the plurality of optical signals and transforms them into electric signals having levels corresponding to the optical signals' intensities, and an A/D converter which converts the plurality of electric signals of the photoelectric transducer into light intensity data and simultaneously outputs the light intensity data and unique addresses of the unit converting elements as digital data; differentiating the light intensity data and original addresses and comparing the unique addresses with values corresponding to the preset wavelengths until the unique addresses is a last address; and performing a light intensity data synthesizing process of accumulatively storing the light intensity data in sequence to the unique addresses by comparing and determining whether each unique address is identical to a value corresponding to a preset wavelength, thereby enabling the control system of the plasma etching equipment to control termination of the etching process a the basis of the accumulatively stored light intensity data.

There are advantages in the apparatus and method described above in that a layer below the one to be treated is neither over-etched nor damaged because the sensitivity to detect an end point of the etching process is improved by using a plurality of light wavelengths, and a point of time when the etching process ends is detected in real time.

### BRIEF DESCRIPTION OF THE DRAWINGS

Objects and aspects of the invention will become apparent from the following description of preferred embodiments with reference to the accompanying drawings in which:

FIG. 1 is a general block diagram for illustrating an end point detector in accordance with an embodiment of the present invention;

FIG. 2 is a flow chart for illustrating operations of a signal operating device shown in FIG. 1;

FIG. 3 is a graph for illustrating a waveform of reflective light detected by using a plurality of light wavelengths in accordance with an embodiment of the present invention; and

FIG. 4 is a graph for illustrating a waveform of reflective light detected by using a single light wavelength in accordance with the prior art.

### DETAILED DESCRIPTION OF THE INVENTION

Hereinafter, a preferred embodiment of the present invention will be described in detail with reference to accompanying drawings. Identical reference numerals are used for parts to perform the same or similar functions even though the parts are shown in other drawings.

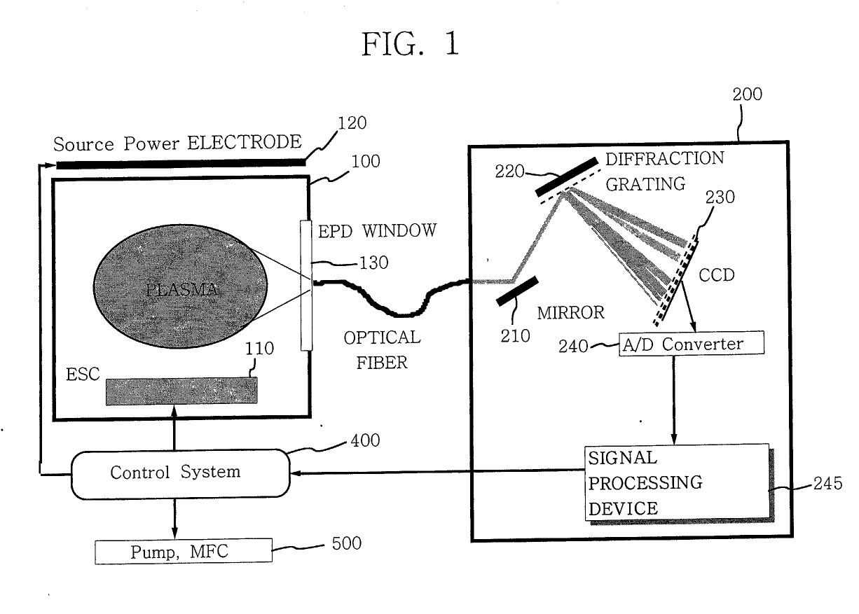

As shown in FIG. 1, a plasma etching device includes: a processing chamber 100 made of a conductive material like aluminum; an electrostatic chuck (ESC) 110 as a lower electrode placed at the bottom of the chamber 100 for acting as a receptor upon which is mounted a semiconductor wafer; and an upper electrode (source power electrode) 120 installed apart from the ESC by a predetermined interval. A gas supplying unit connected at a gas source (not shown) is formed at an upper portion of a periphery wall around the chamber 100, while a gas exhaust connected to a vacuum exhaust (not shown) is formed at a lower portion of the periphery wall around the chamber 100. The ESC is connected through a matching box to a high frequency power source for providing a high frequency current. An EPD window 130, which receives plasma light to detect a point of time when the etching process ends, is installed at the center portion of the wall of the chamber 100. The EPD window is made of a light transmitting material such as quartz.

Meanwhile, an end point detector 200 includes: a diffraction grating 220 as an optical device for diffracting plasma light, generated in the chamber 100, according to the light's spectrum and producing therefrom a plurality of optical signals having different wavelengths; a photoelectric transducer (e.g., a charge-coupled device (CCD)) 230 comprised of a plurality of unit converting elements (e.g., photo diodes) having unique addresses for receiving and converting the plurality of optical signals into electric signals having levels corresponding to the intensity of relevant optical signals; an A/D converter 240 for converting the plurality of electric signals of the photoelectric transducer into light intensity data and simultaneously outputting the converted light intensity data and unique addresses of the unit converting elements as digital data; and a signal processing device 245 for differentiating the light intensity data and unique addresses, performing a light intensity data synthesizing process of accumulatively storing the light intensity data in sequence of the unique addresses by comparing and determining whether the unique addresses are identical to values corresponding to preset wavelengths until the unique address is the final address, and providing the accumulatively stored light intensity data in real time to a control system that operates to terminate the etching process of the plasma etching equipment. At this time, the control system 400 controls the upper electrode of the chamber 100 and a pump MFC 500 in response to operational signals of the signal processing device 245 and determines whether to continue or terminate the etching process.

When an etching process is performed at the plasma etching unit, the chamber 100 is kept in a vacuum state by discharging out the internal gas through the vacuum exhaust. Preferably, the pressure of the chamber 100 is kept between 1 and 5 torr or thereabouts. Then, the high frequency power is applied between the upper and lower electrodes, and an etching gas is supplied through the gas supplying part to the chamber 100. The light emitted from the plasma is applied to the etching end point detector 200 through an optical fiber or the like, and the light reflected is by a reflection mirror 210 and dispersed in space as its reflection angle gets varied by the diffraction grating 220 depending upon wavelength. The light dispersed in space is detected by the photoelectric transducer 230, and an address of each photo diode and the corresponding detected light intensity data are transmitted in series by the A/D converter 240 to the signal processing device 245.

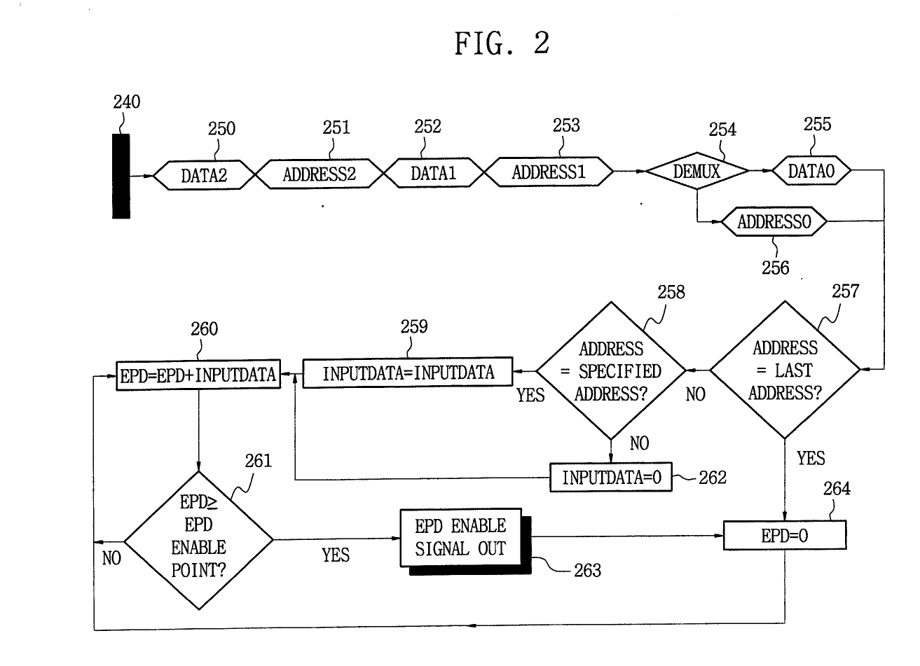

FIG. 2 is an operational flowchart of the signal processing device 245 shown in FIG. 1. The signal processing device 245 receives the light intensity data applied through the A/D converter 240 and the unique address of the corresponding unit converting element as digital data. Then, the digital data are sequentially received at steps 250 through 253 shown in FIG. 2. At step 254, the signal processing device 245 demultiplexes addresses and light intensity data for separation. At step 255, the light intensity data is separated out for temporary storage. The address is separated out at step 256 is compared with one of more preset values at steps 257 and 258. If the address is identical to a preset value (a wavelength value), steps 259 and 260 are performed, and the data corresponding to the address is added to a light intensity value stored in a buffer. If the light intensity value stored in the buffer at step 261 is the same as or greater than a value of an EPD enable point, a step 263 is performed to output an EPD enable signal. Accordingly, the control system 400 shown in FIG. 1 discriminates whether the etching process is stopped or not. If it is determined that the etching process is stopped, the voltage applied to the source power electrode is shut off. Also, the control system 400 can switch the etching mode from a low selection ratio mode to a high selection ratio mode in advance before reception of the enable signal to prevent an over-etch. The etching process is delicately performed during a preset period of time up to reception of the enable signal. If the preset period of time is very short, there will be almost no over-etch even when the lower layer is etched.

The addresses are compared one after another with a plurality of preset wavelengths, and data at the identically corresponding wavelengths are continuously added to the light intensity value stored in the buffer. If the value of the address is a maximum (i.e., the last address) at step 257, the value in the buffer is shown on a monitor or sent to an equipment controller for further use. At this time, the value in the buffer of the signal processing device 245 is reset to 0 by an operation that is performed at step 264. After generation of plasma is stopped by the control system 400, the vacuum state of the chamber 100 is released, and the finished wafer is taken outside. Then, the wafer is washed with de-ionized water to remove any residue.

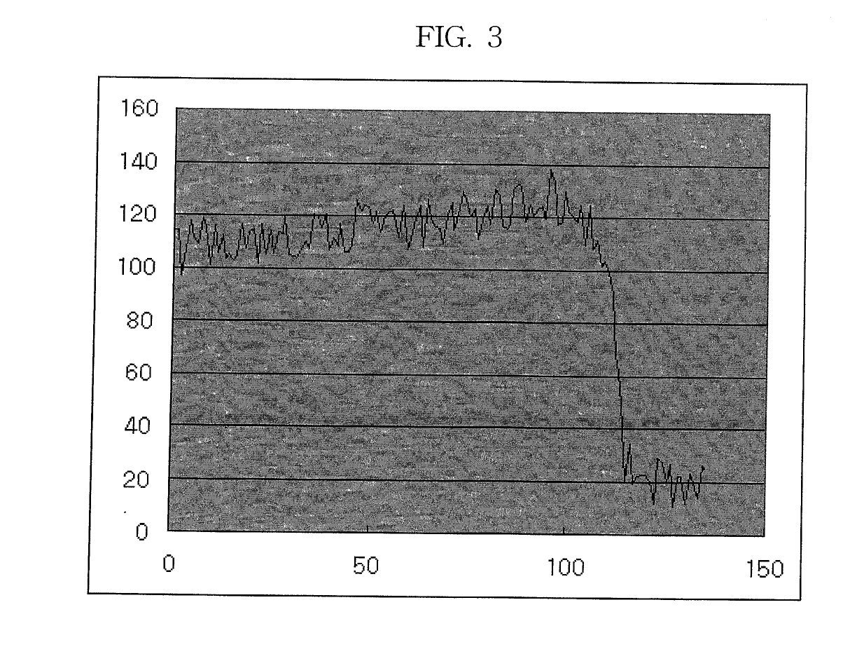

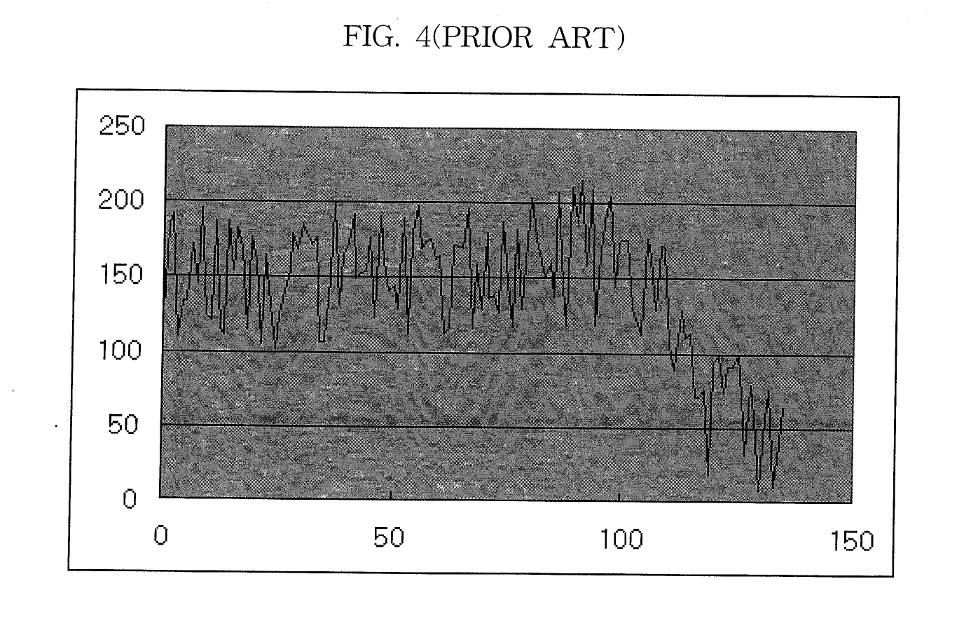

The operations shown in FIG. 2 are programmed and stored in memory (e.g., and EPROM) and applied to actual processes. The final results will be shown below. The wafer to be utilized in an exemplary embodiment of the present invention is made by applying BPSG to a thickness of 4000 angstroms on a silicon substrate and placing a pattern against a contact of 0.13 μm. The ratio of the contact size to the total wafer area is 0.2%. The gas used at the etching process is CF₄. The results of EPD according to the prior art and an embodiment of the present invention are shown in FIGS. 4 and 3, respectively FIG. 3 is a graph illustrating a waveform of the detected reflection light by using a plurality of light wavelengths according to an embodiment of the present invention, and FIG. 4 is a graph illustrating a waveform of the detected reflection light by using a single wavelength in the prior art.

Emission of silicon fluoride (SiF) at 440.8 nm is utilized in the prior art, while values added to the signals relating to SiFₓ (where, x is 1-4) and CO_{y} (y is 0-2) are utilized in the embodiment of the present method.

In the preferred embodiment of the present invention, wavelengths for EPD may be selected and utilized by a statistical method named PCA (principal component analysis) in which wavelengths tend to change according to operational conditions. In the prior art shown in FIG. 4, the exposed area of silicon oxide layer is so small that, with a mixture of noise, it is difficult to detect the end point of the etching process. However, as shown in the graph of FIG. 3, the addition of signal intensity at multiple wavelengths in the preferred embodiment makes it easy to detect an end point of the etching process.

While a preferred embodiment is used for descriptions of present invention with the accompanying drawings, it is apparent to people skilled in the field that various changes and modifications can be made onto the present invention within the scope of the invention.

As described above, there are advantages in the end point detector for an etching process of the present invention, and its related method in that a plurality of light wavelengths are utilized to improve the sensitivity to detect a point of time when the etching process ends and in that a point of time when the etching process ends is detected in real time to thereby prevent a lower layer from being over-etched or damaged. Therefore, the process to detect an end point of the etching process becomes stabilized for a better reliability of final products.

What is claimed is:

1. An etching end point detector for detecting an etching end point by using plasma light generated during a plasma process in a chamber of plasma etching equipment, the detector comprising:
an optical device for diffracting plasma light generated in the chamber according to a spectrum of the light and turning the light into a plurality of optical signals having different wavelengths;
a photoelectric transducer including of a plurality of unit converting elements having their own unique addresses for receiving the plurality of optical signals and converting the plurality of optical signals into corresponding electric signals each having an intensity corresponding to an intensity of the corresponding optical signal;
an A/D converter for converting the plurality of electric signals of the photoelectric transducer into light intensity data and simultaneously outputting the light intensity data and the unique addresses of the unit converting elements as digital data; and
a signal processing device for differentiating the light intensity data and unique addresses, performing a light intensity data synthesizing process of accumulatively storing the light intensity data in sequence to the unique addresses by comparing and determining whether each unique address is identical to a value corresponding to a preset wavelength, until the original address is a last address, and providing the accumulatively stored light intensity data in real time to a control system that operates to terminate the etching process of the plasma etching equipment.

2. A detector, as in claim 1, wherein the optical device is made up of diffraction gratings.

3. A detector, as in claim 1, wherein the photoelectric transducer is made up of charge coupled device elements.

4. The detector, as in claim 1, where the signal operational device is to accumulatively store light intensity data at an internal buffer.

5. A method of detecting an etching end point using plasma light generated in a chamber of plasma etching equipment during a plasma process, the method comprising the steps of:
setting up a diffraction grating which diffracts the plasma light generated in the chamber according to a spectrum of the light and turning the light into a plurality of optical signals having different wavelengths, a charge coupling device, including a plurality of unit converting elements having their own unique addresses, which receives the plurality of optical signals and converts the optical signals into corresponding of electric signals each having a level corresponding to an intensity of the corresponding optical signal, and an A/D converter which converts the plurality of electric signals of the charge coupling device into light intensity data and simultaneously outputs the light intensity data and unique addresses of the unit converting elements as digital data;
differentiating the light intensity data and unique addresses and comparing the unique addresses with values corresponding to the preset wavelengths until the unique address is a final address;
performing a light intensity data synthesizing process of accumulatively storing the light intensity data in sequence to the unique addresses by comparing and determining whether the unique addresses are identical to values corresponding to preset wavelengths; and
enabling a control system of the plasma etching equipment to control termination of the etching process on based on the accumulatively stored light intensity data.

6. An etching end point detector for detecting an end point of an etching process, the detector comprising:
an optical device receiving light generated in a chamber during the etching process and producing from the light a plurality of optical signals having different corresponding wavelengths;
signal converting means receiving the plurality of optical signals and converting the plurality of optical signals into corresponding light intensity values indicating an intensity of the corresponding optical signal; and
a signal processor accumulating selected ones of the light intensity values corresponding to predetermined wavelengths to produce an EPD value, and in response to the EPD value, determining an end point of the etching process.

7. The detector of claim 6, wherein the optical device includes a diffraction grating.

8. The detector of claim 6, wherein the signal converting means includes a charge-coupled device (CCD).

9. The detector of claim 8, wherein the signal converting means further comprises an analog-to-digital converter receiving an output of the charge-coupled device and producing therefrom the light intensity values.

10. The method of claim 8, wherein the CCD includes a plurality of detectors each having a unique address and each producing a corresponding one of the light intensity values corresponding to one of the wavelengths, and wherein the signal converting means simultaneously outputs the light intensity values and the unique addresses of the corresponding detectors.

11. The method of claim 10, wherein the signal processing device compares each unique address to preset addresses corresponding to the predetermined wavelengths and accumulates the corresponding light intensity values when the unique address matches one of the preset addresses.

12. The detector of claim 6, wherein the signal processor compares the EPD value to a predetermined threshold and in response thereto produces an enable signal.

13. The detector of claim 12, wherein the signal processor provides the enable signal to a control system controlling the etching process.

14. A method of detecting an end point of an etching process, comprising:
receiving light generated in a chamber during the etching process and producing from the light a plurality of optical signals having different wavelengths;
converting the plurality of optical signals into corresponding light intensity values indicating an intensity of the corresponding optical signal; and
accumulating selected ones of the light intensity values corresponding to predetermined wavelengths to produce an EPD value, and;
in response to the EPD value, determining an end point of the etching process.

15. The method of claim 14, wherein determining an end point of the etching process comprises comparing the EPD value to a predetermined threshold.

16. The method of claim 15, further comprising providing the enable signal to a control system controlling the etching process.

17. The method of claim 16, further comprising terminating the etching process in response to the control signal.

18. The method of claim 14, further comprising terminating the etching process in response to determining the end point of the etching process.

19. The method of claim 14, further comprising outputting each light intensity value together with a corresponding unique address of a detector which produced each light intensity value, the unique address indicating a wavelength of one of the optical signals corresponding to the corresponding light intensity value.

20. The method of claim 19, wherein accumulating selected ones of the light intensity values corresponding to predetermined wavelengths comprises:
comparing each unique address to preset addresses corresponding to the predetermined wavelengths; and
accumulating the corresponding light intensity values when the unique address matches one of the preset addresses.
